(19) United States
(12) Patent Application Publication
(10) Pub. No.: US 2019/0221637 A1
(43) Pub. Date: Jul. 18, 2019

(54) LOW-TEMPERATURE POLYSILICON THIN FILM TRANSISTOR AND MANUFACTURING METHOD AND DISPLAY DEVICE THEREOF

(71) Applicant: Wuhan China Star Optoelectronics Semiconductor Display Technology Co., Ltd, Wuhan, Hubei (CN)

(72) Inventor: Songshan LI, Wuhan, Hubei (CN)

(21) Appl. No.: 15/578,155

(22) PCT Filed: Sep. 5, 2017
(86) PCT No.: PCT/CN2017/100580

§ 371 Date: Nov. 29, 2017

(30) Foreign Application Priority Data
Jul. 27, 2017 (CN) 201710624547.2

(51) Int. Cl. H01L 29/06; H01L 29/66; H01L 29/786; H01L 27/12; G02F 1/1333; H01L 51/52

(52) U.S. Cl. CPC H01L 29/0638; H01L 29/0653; H01L 29/66765; H01L 51/5296; H01L 29/78678; H01L 27/1214; G02F 1/1333; H01L 29/78609

(57) ABSTRACT

The disclosure provides a low-temperature polysilicon thin film transistor (LTPS TFT) including: a substrate; a gate; a gate insulating layer; a polysilicon layer disposed on the gate insulating layer and including a groove; a doped polysilicon layer disposed on the polysilicon layer and including a through hole completely exposing the groove; an etching barrier layer disposed on the gate insulating layer and the doped polysilicon layer and filling the through hole and the groove and including a first and a second via holes exposing the doped polysilicon layers; a source and a drain disposed on the etching barrier layer and filling the two via holes respectively; and a passivation layer. The disclosure also provides a manufacturing method and a display device of a LTPS TFT. The disclosure can prevent the source and the drain from directly contacting the polysilicon layer, thereby reducing the leakage current of the LTPS TFT.

### RELATED APPLICATIONS

The present application is a National Phase of International Application Number PCT/CN2017/100580, filed Sep. 5, 2017, and claims the priority of China Application No. 201710624547.2, filed Jul. 27, 2017.

### FIELD OF THE DISCLOSURE

The disclosure relates to a thin film transistor fabrication technology, and more particularly to a low-temperature polysilicon thin film transistor, and a manufacturing method and a display device thereof.

### BACKGROUND

With the evolution of optoelectronics and semiconductor technology, the flat panel display is booming, and in many flat panel displays, liquid crystal display (LCD) and organic light emitting diode (OLED) display have become the mainstream market due to their high space utilization efficiency, low power consumption, no radiation, low electromagnetic interference and many other superior features.

At present, amorphous silicon thin film transistor (a-Si TFT) is widely used as a switching element for LCD and OLED displays, but a-Si TFT LCD is still restricted on satisfying the requirements of thin, lightweight, high-precision, high brightness, high reliability, low power consumption, and the like. Compared with a-Si TFT, low-temperature polysilicon (LTPS) TFT has obvious advantages in meeting the above requirements.

However, in the current low-temperature polysilicon thin film transistor, because the source and drain can contact the undoped polysilicon layer, which will cause the increase of the leakage current I_{off} of low-temperature polysilicon thin film transistor, thus affecting the characteristics of low-temperature polysilicon thin film transistor, and then affecting the display quality of LCD and OLED display.

### SUMMARY

To solve the problems of the prior art, the object of the disclosure is to provide a low-temperature polysilicon thin film transistor capable of reducing a leakage current, and a manufacturing method and a display device thereof.

According to an aspect of the disclosure, there is provided a low-temperature polysilicon thin film transistor comprising a substrate; a gate disposed on the substrate; a gate insulating layer disposed on the substrate and the gate; a polysilicon layer disposed on the gate insulating layer, and the polysilicon layer including a groove; a doped polysilicon layer disposed on the polysilicon layer, the doped polysilicon layer including a through hole, the through hole completely exposes the groove; an etching barrier layer disposed on the gate insulating layer and the doped polysilicon layer and filling the through hole and the groove, and the etching barrier layer having a first via hole and a second via hole, and the first via hole and the second via hole exposing the doped polysilicon layer respectively; the source filling the first via hole to contact the doped polysilicon layer exposed by the first via hole, the drain filling the second via hole to contact the doped polysilicon layer exposed by the second via hole; and a passivation layer disposed on the source, the drain, and the etching barrier layer.

Optionally, the doped polysilicon layer is doped with boron ions.

Optionally, the etching barrier layer is made of silicon oxide and/or silicon nitride.

According to another aspect of the disclosure, there is also provided a display device, including the low-temperature polysilicon thin film transistor.

According to further another aspect of the disclosure, there is provided a manufacturing method of a low-temperature polysilicon thin film transistor, including the steps of: providing a substrate; forming a gate on the substrate; forming a gate insulating layer on the substrate and the gate; forming a polysilicon layer on the gate insulating layer and a doped polysilicon layer located on the polysilicon layer; forming a through hole in the doped polysilicon layer and forming a groove on the polysilicon layer, and the through hole completely exposing the groove; forming a first via hole and a second via hole in the etching barrier layer, and the first via hole and the second via hole respectively exposing the doped polysilicon layer; forming a source and a drain on the etching barrier layer, and the source filling the first via hole to contact a doped polysilicon layer exposed by the first via hole, and the drain filling a second via hole to contact the doped polysilicon layer exposed by the second via hole; and forming a passivation layer on the source, the drain, and the etching barrier layer.

Optionally, the method of the step of forming a polysilicon layer on the gate insulating layer and a doped polysilicon layer on the polysilicon layer” includes forming an amorphous silicon layer on the gate insulating layer; implanting ions in the amorphous silicon layer by using ion implantation technique; recrystallizing the amorphous silicon layer by using a rapid thermal annealing technique to form a polysilicon layer and a doped polysilicon layer on the polysilicon layer.

Optionally, the method of the step of forming a through hole in the doped polysilicon layer and forming a groove on the polysilicon layer includes forming a through hole in the doped polysilicon layer and forming a groove on the polysilicon layer by using a halftone mask process.

Optionally, the etching barrier layer is made of silicon oxide and/or silicon nitride.

Optionally, the ions implanted by the ion implantation technique are boron ions.

The beneficial effect of this disclosure is that the disclosure can prevent the source and the drain from directly contacting the polysilicon layer, thereby reducing the leakage current of the low-temperature polysilicon thin film transistor, and further improving the characteristics of the low-temperature polysilicon thin film transistor.

### BRIEF DESCRIPTION OF THE DRAWINGS

The foregoing and other aspects, features and advantages of the embodiment of the invention will become more fully clear from the following description made in connection with the accompanying drawings and in which:

FIG. 1 is a schematic structural view of a low-temperature polysilicon thin film transistor according to an embodiment of the disclosure;

FIGS. 2A to 2I are schematic diagrams of a manufacturing process of a low-temperature polysilicon thin film transistor according to an embodiment of the disclosure.

### DETAILED DESCRIPTION OF PREFERRED EMBODIMENTS

Hereinafter, embodiments of the disclosure will be described in detail with reference to the accompanying drawings. This disclosure may, however, be embodied in many different forms and should not be construed as limited to the embodiments set forth herein. Rather, these embodiments are provided to explain the principles of the disclosure and its practical application so as to enable those skilled in the art to understand the various embodiments of the disclosure and various modifications that are suitable for a specific intended application.

In the drawings, the thickness of the layers and regions is exaggerated in order to clarify the device. The same reference numerals refer to like elements throughout the specification and drawings.

It will be understood that when an element such as a layer, a film, a region, or a substrate is referred to as being “on” another element, the element may be directly on the other element, or an intermediate element may also be present. Optionally, there is no intermediate element when the element is referred to as being “directly on” the other element.

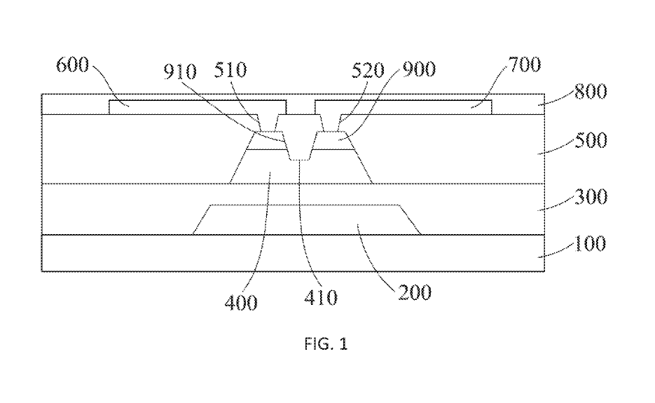

FIG. 1 is a schematic structural view of a low-temperature polysilicon thin film transistor according to an embodiment of the disclosure.

Referring to FIG. 1, a low-temperature polysilicon thin film transistor according to an embodiment of the disclosure includes a substrate 100, a gate 200, a gate insulating layer 300, a polysilicon layer 400, an etching barrier layer 500, a source 600, a drain 700, a passivation layer 800, and a doped polysilicon layer 900.

Specifically, the substrate 100 may be, for example, a transparent glass substrate or a resin substrate, but the disclosure is not limited thereto.

The gate 200 is disposed on the substrate 100. The gate 200 may be a molybdenum-aluminum-molybdenum (MoAlMo) structure or a titanium-aluminum-titanium (TiAlTi) structure, or may be a single-layer structure of molybdenum or a single-layer structure of aluminum, but the disclosure is not limited thereto.

The gate insulating layer 300 is disposed on the gate 200 and the substrate 100. Here, the gate insulating layer 300 may be, for example, a SiNₓ/SiOₓ structure formed on the gate 200 and the substrate 100, but the disclosure is not limited thereto, for example, the gate insulating layer 300 may be a single-layer structure of SiNₓ or SiOₓ.

The polysilicon layer 400 is disposed on the gate insulating layer 300. The polysilicon active layer 400 includes a groove 410.

The doped polysilicon layer 900 is disposed on the polysilicon layer 400. The doped polysilicon layer 900 includes a through hole 910, and the through hole 910 completely exposes the groove 410.

The etching barrier layer 500 is disposed on the doped polysilicon layer 900 and the gate insulating layer 300, and the etching barrier layer 500 fills the through hole 910 and the groove 410 to contact the polysilicon layer 400. In addition, the etching barrier layer 500 includes a first via hole 510 and a second via hole 520, the first via hole 510 exposes the doped polysilicon layer 900 located at one side (left side) of the through hole 910 and the groove 410, and the second via hole 520 exposes the doped polysilicon layer 900 located at the other side (right side) of the through hole 910 and the groove 410. In the present embodiment, the etching barrier layer 500 is formed of SiNₓ and/or SiOₓ, but the disclosure is not limited thereto.

The source 600 and the drain 700 are disposed on the etching barrier layer 500, the source 600 fills the first via hole 510 to contact the doped polysilicon layer 900 located one side of the through hole 910 and the groove 410, and the drain 700 fills the second via hole 520 to contact the doped polysilicon layer 900 located at the other side of the through hole 910 and the groove 410. The source 600 and the drain 700 may be formed of molybdenum aluminum molybdenum (MoAlMo) structure or titanium aluminum titanium (TiAlTi) structure, or may be a single-layer structure of molybdenum or a single-layer structure of aluminum, but the disclosure is not limited thereto.

The passivation layer 800 is disposed on the source 600, the drain 700, and the etching barrier layer 500. In the present embodiment, the passivation layer 800 is formed of silicon oxide (such as SiOx), but the disclosure is not limited thereto.

The low-temperature polysilicon thin film transistor according to an embodiment of the disclosure can be applied to a display device such as a liquid crystal display device and an OLED display device. The low-temperature polysilicon thin film transistor of the embodiment of the disclosure can prevent the source 600 and the drain 700 from directly contacting the polysilicon layer 410, thereby reducing the leakage current of the low-temperature polysilicon thin film transistor and further improving the characteristics of the low-temperature polysilicon thin film transistor.

The manufacturing method of the low-temperature polysilicon thin film transistor according to the embodiment of the disclosure will be described in detail below.

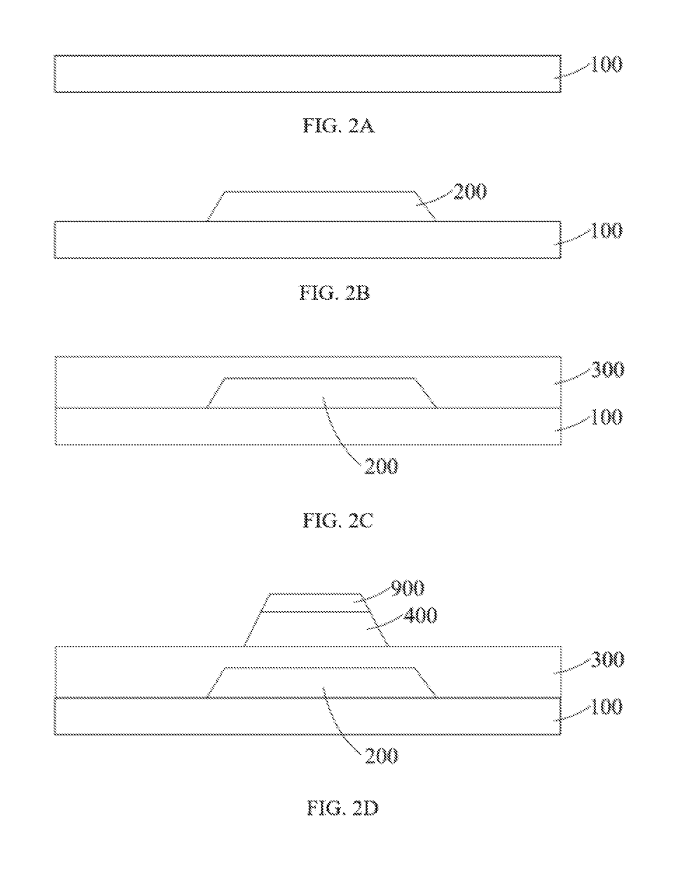

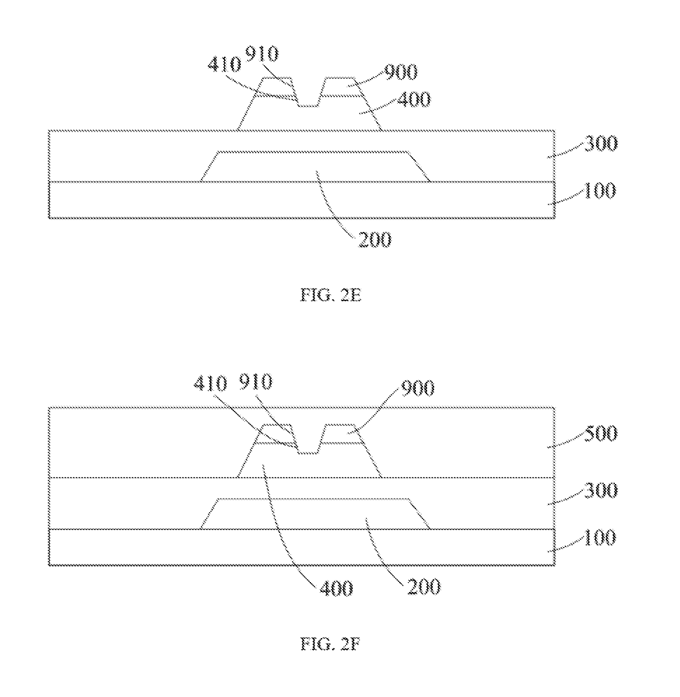

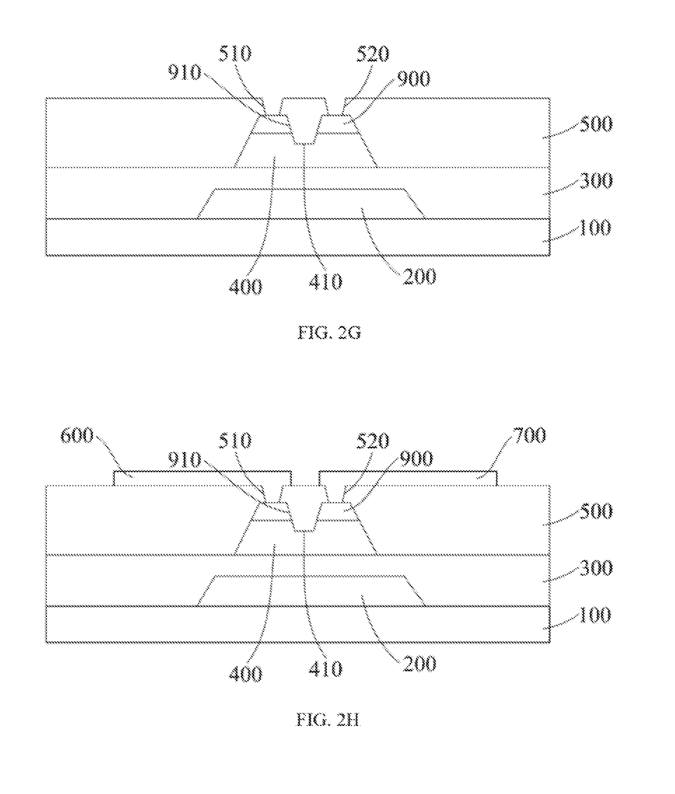

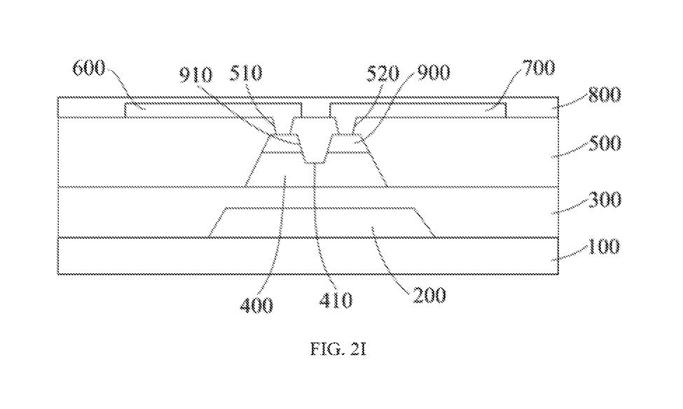

FIGS. 2A to 2I are schematic diagrams of a manufacturing process of a low-temperature polysilicon thin film transistor according to an embodiment of the disclosure.

A manufacturing method of a metal oxide thin film transistor according to an embodiment of the disclosure includes:

Step 1: referring to FIG. 2A, providing a substrate 100; the substrate 100 may be, for example, an insulating and transparent glass substrate or a resin substrate, but the disclosure is not limited thereto.

Step 2: referring to FIG. 2B, forming a gate 200 on the substrate 100; the gate 400 may be a molybdenum-aluminum-molybdenum (MoAlMo) structure or a titanium-aluminum-titanium (TiAlTi) structure, or may be a single-layer structure of molybdenum or a single-layer structure of aluminum, but the disclosure is not limited thereto.

Step 3: referring to FIG. 2C, forming a gate insulating layer 300 on the substrate 100 and the gate 200; here, the gate insulating layer 300 may be, for example, a SiNₓ/SiOₓ structure formed on the semiconductor body layer 210; however, the disclosure is not limited thereto. For example, the gate insulating layer 300 may be a single-layer structure of SiNₓ or SiOₓ.

Step 4: referring to FIG. 2D, forming a polysilicon layer 400 on the gate insulating layer 300 and a doped polysilicon layer 900 on the polysilicon layer.

Here, the method of forming the polysilicon layer 400 and the doped polysilicon layer 900 on the polysilicon layer specifically includes: first forming an amorphous silicon layer on the gate insulating layer 300 by plasma enhanced chemical vapor deposition (PECVD); next, implanting ions (such as boron ions or the like) in the amorphous silicon layer by ion implantation technique; and then, recrystallizing the amorphous silicon layer in the manner of rapid thermal annealing so as to form the polysilicon layer 400 and the doped polysilicon layer 900 on the polysilicon layer 400.

Step 5: referring to FIG. 2E, forming a through hole 910 in the doped polysilicon layer 900, and forming a groove 410 on the polysilicon layer 400, and the through hole 910 completely exposes the groove 410.

Here, the specific method of forming the through hole 910 and the groove 410 is to form the through hole 910 in the doped polysilicon layer 900 and to form a groove 410 on the polysilicon layer 400 by a half tone mask (HTM) process, but the disclosure is not limited thereto.

Step 6: referring to FIG. 2F, forming an etching barrier layer 500 on the gate insulating layer 300, the polysilicon layer 400, and the doped polysilicon layer 900; here, the etching barrier layer 500 is formed of silicon oxide (such as SiOx) and/or silicon nitride (such as SiNₓ), but the disclosure is not limited thereto.

Step 7: referring to FIG. 2G, forming a first via hole 510 and a second via hole 520 in the etching barrier layer 500; the first via hole 510 exposes the doped polysilicon layer 900 located at one side (left side) of the through hole 910 and the groove 410, and the second via hole 520 exposes the doped polysilicon layer 900 located at the other side (right side) of the through hole 910 and the groove 410.

Step 8: referring to FIG. 2H, forming a source 600 and a drain 700 on the etching barrier layer 500; the source 600 fills the first via hole 510 to contact the doped polysilicon layer 900 located at one side of the through hole 910 and the groove 410 900, the drain 700 fills the second via hole 520 to contact the doped polysilicon layer 900 located at the other side of the through hole 910 and the groove 410. The source 600 and the drain 700 may be made of molybdenum aluminum molybdenum (MoAlMo) structure or titanium aluminum titanium (TiAlTi) structure, or may be a single-layer structure of molybdenum or a single-layer structure of aluminum, but the disclosure is not limited thereto.

Step 9: referring to FIG. 2I, forming a passivation layer 800 on the source 600, the drain 700, and the etching barrier layer 500. Here, the passivation layer 800 is formed of silicon oxide (such as SiOₓ), but the disclosure is not limited thereto.

While the disclosure has been particularly shown and described with reference to exemplary embodiments thereof, it will be understood by those skilled in the art that various changes in form and details may be made therein without departing from the spirit and scope of the disclosure as defined by the appended claims and their equivalents.

What is claimed is:

1. A low-temperature polysilicon transistor, comprising:
a substrate;
a gate disposed on the substrate;
a gate insulating layer disposed on the substrate and the gate;
a polysilicon layer disposed on the gate insulating layer, wherein the polysilicon layer comprises a groove;
a doped polysilicon layer disposed on the polysilicon layer, wherein the doped polysilicon layer comprises a through hole, the through hole completely exposes the groove;
an etching barrier layer disposed on the gate insulating layer and the doped polysilicon layer and filling the through hole and the groove, wherein the etching barrier layer comprises a first via hole and a second via hole, the first via hole and the second via hole expose the doped polysilicon layers respectively;
a source and a drain disposed on the etching barrier layer, wherein the source fills the first via hole to contact the doped polysilicon layer exposed by the first via hole, and the drain fills the second via hole to contact the doped polysilicon layer exposed by the second via hole; and
a passivation layer disposed on the source, the drain, and the etching barrier layer.

2. The low-temperature polysilicon thin film transistor according to claim 1, wherein the doped polysilicon layer is doped with boron ions.

3. The low-temperature polysilicon thin film transistor according to claim 1, wherein the etching barrier layer is made of silicon oxide and/or silicon nitride.

4. A display device, wherein comprises the low-temperature polysilicon thin film transistor according to claim 1.

5. A manufacturing method of a low-temperature polysilicon thin film transistor, comprising the steps of:
providing a substrate;
forming a gate on the substrate;
forming a gate insulating layer on the substrate and the gate;
forming a polysilicon layer on the gate insulating layer and a doped polysilicon layer on the polysilicon layer;
forming a through hole in the doped polysilicon layer and forming a groove on the polysilicon layer, and the through hole completely exposing the groove;
forming an etching barrier layer on the doped polysilicon layer, the gate insulating layer, and the polysilicon layer;
forming a first via hole and a second via hole in the etching barrier layer, wherein the first via hole and the second via hole respectively expose the doped polysilicon layer;
forming a source and a drain on the etching barrier layer, wherein the source fills the first via hole to contact a doped polysilicon layer exposed by the first via hole, and the drain fills the second via hole to contact the doped polysilicon layer exposed by the second via hole; and
forming a passivation layer on the source, the drain, and the etching barrier layer.

6. The manufacturing method according to claim 5, wherein the step of forming a polysilicon layer on the gate insulating layer and a doped polysilicon layer on the polysilicon layer comprises:
forming an amorphous silicon layer on the gate insulating layer;
implanting ions in the amorphous silicon layer by using ion implantation technique; and
recrystallizing the amorphous silicon layer by using a rapid thermal annealing technique to form a polysilicon layer and a doped polysilicon layer on the polysilicon layer.

7. The manufacturing method according to claim 5, wherein the step of forming a through hole in the doped polysilicon layer and forming a groove on the polysilicon layer comprises forming a through hole in the doped polysilicon layer and forming a groove on the polysilicon layer by using a halftone mask process.

8. The manufacturing method according to claim 5, wherein the etching barrier layer is made of silicon oxide and/or silicon nitride.

9. The manufacturing method according to claim 6, wherein the ions implanted by the ion implantation technique are boron ions.
